(19) United States
(12) Patent Application Publication
(10) Pub. No.: US 2023/0296432 A1
(43) Pub. Date: Sep. 21, 2023

(54) COMPACT WIDE FIELD IMAGER FOR LASER DETECTION

(71) Applicant: Marek Kowarz, Henrietta, NY (US)

(72) Inventor: Marek Kowarz, Henrietta, NY (US)

(21) Appl. No.: 18/200,707

(22) Filed: May 23, 2023

Related U.S. Application Data
(63) Continuation-in-part of application No. 17/475,518, filed on Sep. 15, 2021.
(60) Provisional application No. 63/347,117, filed on May 31, 2022.
(60) Provisional application No. 63/080,149, filed on Sep. 18, 2020.

(51) Int. Cl. G01J 1/42; G01J 1/44; G01J 1/04; G01J 3/50; G01S 3/781

(52) U.S. Cl. CPC G01J 1/4257; G01J 1/44; G01J 1/0407; G01J 3/502; G01S 3/781; G01J 2001/448

(57) ABSTRACT

An apparatus for characterization of one or more light sources over a field of view has an image relay disposed to relay a first image plane to a second image plane. An aperture defines the field of view at the first image plane. A diffraction grating in the path of light through the aperture is configured to form, on the first image plane, for at least one light source, a light pattern having at least two diffraction orders of light from the corresponding light source. An image sensor array is configured to provide image data from the light pattern at the second image plane.

### CROSS REFERENCE TO RELATED APPLICATIONS

The present application is a continuation-in-part of U.S. Patent application Ser. No. 17/475,518 entitled “Lensless Imager for Laser Detection” by Marek Kowarz et al. and filed 15 Sep. 2021, which in turn claims the benefit of U.S. Provisional Application Ser. 63/080,149 by Marek Kowarz et al. and filed 18 Sep. 2020; and further claims the benefit of U.S. Provisional Application Ser. 63/347,117 entitled “Compact Wide Field Imager for Laser Detection” by Marek Kowarz, filed 31 May 2022 and incorporated herein in its entirety.

### FIELD

The present disclosure generally relates to wide field-of-view light characterization apparatus and more particularly to a laser detection device that employs diffraction to determine laser source location, intensity, and wavelength.

### BACKGROUND

There is increasing awareness in the importance of laser detection and warning systems in military applications, as well as in commercial flight, and industrial fields. Laser light energy can be directed toward personnel and equipment in laser attacks, posing increasing risk to infantry and to air and vehicle crews. Modern battlefield technology, using techniques such as laser range finding, missile guidance, and directed energy weapons, also threaten the safety of equipment, personnel, vehicles, buildings, and other infrastructure.

Rapid detection of the source and characteristics of laser light is critical in supporting response and mitigation to ensure the safety of personnel at risk for laser exposures, as well as protecting a wide variety of land, air, sea, and space vehicles. While laser detection systems have been developed for mounting on helicopters and ground combat vehicles, their relative cost and factors of size, weight, and power (SWaP) render existing solutions unacceptable for personnel protection in any type of wearable system or for broader deployment on vehicles.

### SUMMARY

The Applicant addresses the problem of a compact system for laser detection capable of determining laser source location, intensity, and wavelength. With this object, the Applicant describes apparatus for laser detection that is smaller, lighter, and lower cost than existing solutions, that is capable of high levels of accuracy, and that overcomes many of the shortcomings of other proposed solutions, as outlined previously in the background section.

The Applicants' solution provides a wide field-of-view (FOV) laser detection device that employs diffraction of light to effectively and quickly distinguish laser light from broadband light sources, including bright sunlight, headlights and LED sources, such as flashlights. Advantageously, the Applicants' system can detect a wide range of laser sources, including short-wave infrared lasers, using low-cost silicon-based image sensors. Furthermore, the system does not require conventional large wide field-of-view curved lenses or mirrors; instead, compact planar optical components can be used for light transmission and redirection. The Applicants' device employs diffractive optical components that can be fabricated at wafer scale with semiconductor and related microfabrication processes and equipment.

From an aspect of the present disclosure, there is provided an apparatus for characterization of one or more light sources over a field of view, comprising:
a) an image relay disposed to relay a first image plane to a second image plane;
b) an aperture disposed to define the field of view at the first image plane;
c) a diffraction grating in the path of light through the aperture and configured to form, on the first image plane, for at least one light source, a light pattern having at least two diffraction orders of light from the corresponding light source;
and
d) an image sensor array configured to provide image data from the light pattern at the second image plane.

### DRAWINGS

FIG. 1A is a schematic diagram that shows the operating principles of a compact imaging device for laser detection.

FIG. 1B is a schematic diagram that illustrates operation in an environment having multiple light sources of different types, along with scene content.

FIG. 1C is a simplified diagram showing aspects of various types of light incident on the image plane of FIG. 1A.

FIG. 2A is a simplified diagram showing the primary components of a compact imager for laser detection.

FIGS. 2B and 2C show the structure of a fiber optic faceplate used as an image relay, from a side view and top view, respectively.

FIG. 2D shows a triplet lens used as an image relay.

FIG. 2E is a simplified diagram showing a preferred embodiment of a compact imager for infrared laser detection.

FIGS. 3A and 3B are simplified schematic diagrams, from a side view, showing diffraction of on-axis and off-axis laser light, respectively.

FIGS. 3C and 3D are simplified schematic diagrams showing diffraction of on-axis and off-axis sunlight, respectively.

FIG. 4 is a simplified schematic diagram that shows diffraction effects wherein both a laser source and the Sun are within the field of view.

FIG. 5 compares structure of a portion of a 1D diffraction grating with a portion of a 2D diffraction grating.

FIGS. 6A and 6B are simplified schematic diagrams, from the image plane, showing diffraction of on-axis and off-axis laser light, for 1D and 2D diffraction gratings, respectively.

FIG. 6C is an exemplary image acquired from diffraction of green laser light through an aperture with a 2D diffraction grating.

FIGS. 7A and 7B are simplified schematic diagrams, from the image plane, showing diffraction of on-axis and off-axis sunlight, for 1D and 2D diffraction gratings, respectively.

FIG. 7C is an image acquired from diffraction of sunlight through an aperture with a 2D diffraction grating.

FIG. 8 is a graph showing the spectral response of a color image sensor from blue to near-infrared wavelengths.

FIG. 9A is a graph showing the spectrum from a 520 nm green laser.

FIG. 9B is a graph showing the spectrum from a 465 nm blue LED.

FIG. 9C is a graph showing the spectrum from an 850 nm near-infrared LED.

FIG. 10 is a schematic diagram that shows, from a side view, components of a compact image sensor for simultaneous detection of visible and short-wave infrared lasers.

FIG. 11A shows example specifications for a compact imager for infrared laser detection according to an embodiment.

FIG. 11B is a graph showing position of diffraction orders vs. angle for detection of a 1064 nm laser.

FIG. 11C is a graph showing position of diffraction orders vs. angle for detection of a 1550 nm laser.

### DESCRIPTION

The following is a detailed description of the preferred embodiments of the disclosure, reference being made to the drawings in which the same reference numerals identify the same elements of structure in each of the several figures.

Where they are used, the terms “first”, “second”, and so on, do not necessarily denote any ordinal, sequential, or priority relation, but are simply used to more clearly distinguish one element or set of elements from another, unless specified otherwise.

In the context of the present disclosure, the term “coupled” is intended to indicate a mechanical association, connection, relation, or linking, between two or more components, such that the disposition of one component affects the spatial disposition of a component to which it is coupled. For mechanical coupling, two components need not be in direct contact, but can be linked through one or more intermediary components.

In the context of the present disclosure, the phrase “point light source”, more succinctly termed “point source” refers to a source of light that can be modeled as an ideal point in object space having a single location and minimal spatial extent. Furthermore, a point source as used herein may emit light in all directions, as is the case for the sun, or may emit highly collimated light, as can be obtained from a laser, or may emit light in only a certain range of angles.

The term “exemplary” indicates that the described device or application is used as an example, rather than implying that it is an ideal.

In the context of the present disclosure, two components or devices are said to be “in signal communication” when the components or devices are capable of communicating with each other via signals that travel over some type of signal path. Signal paths may include physical, electrical, magnetic, electromagnetic, optical, wired, and/or wireless connections between the first device and/or component and second device and/or component, and may also include additional devices and/or components between the first device and/or component and second device and/or component. Signal communication may be wired or wireless.

Characterization of a light source refers to measuring its light energy from various aspects. For example, spectral characterization, as the phrase is used herein, relates to measurements that account for the range of wavelengths included in the light and that profile the distribution of energy at particular wavelengths and related spectral qualities of the light energy.

Embodiments of the present disclosure address the problem of laser detection and other characterization using methods that employ diffraction and compact imaging systems. The Applicant's device acquires and processes image data using a simple optical system, preferably with components having planar surfaces, to determine laser position, intensity, and wavelength over a wide field of view (FOV).

In order to more fully appreciate the approach and scope of the Applicant's apparatus, it is useful to consider the simplified architecture of the Applicant's solution and the behavior of light transmitted through a small aperture with a diffraction grating.

In the context of the present disclosure and for the sake of consistency, the zeroth or 0^{th} order light is counted as a diffraction order, rather than considered “non-diffracted” light. Thus, for example, the 0^{th} order and +1^{st} order light count as two diffraction orders.

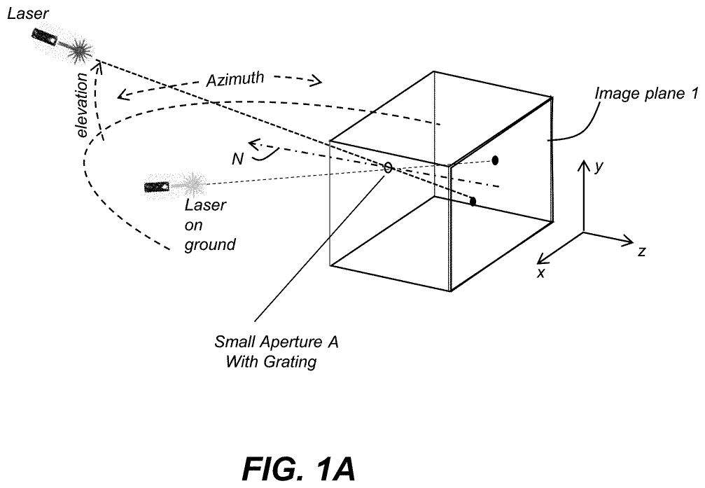

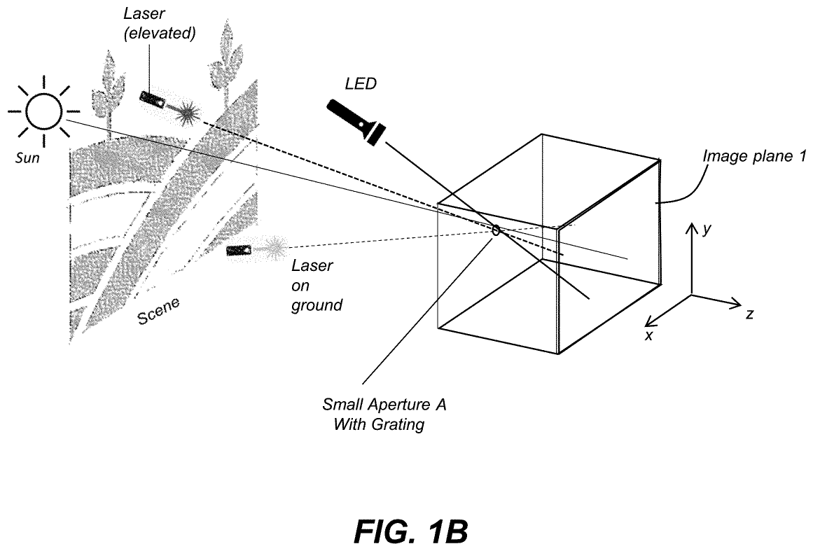

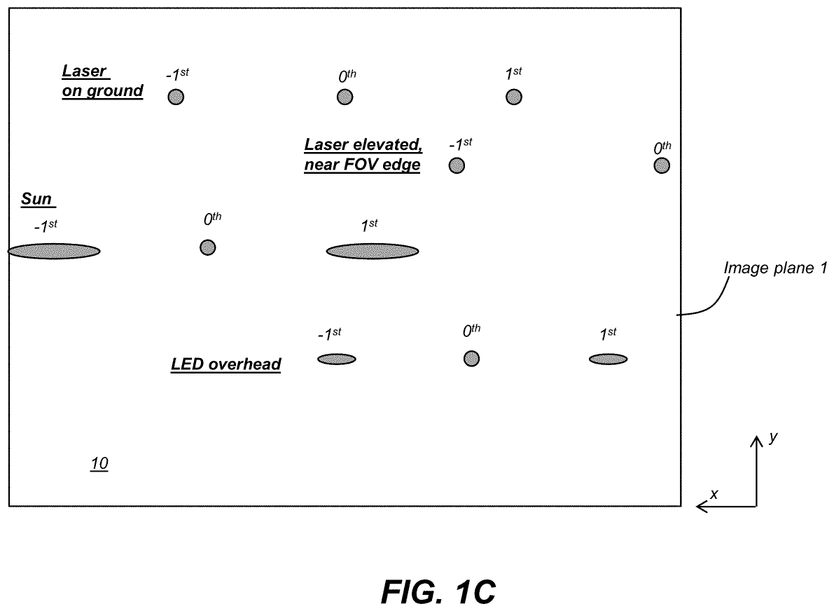

FIG. 1A is a schematic diagram that shows, in simplified form, the operating principles of a compact wide field of view apparatus for laser detection, for lasers pointed toward the device. Geometry of an aperture A and an image plane 1 define a field of view that includes, for each of one or more light sources, a corresponding light path that extends along a central ray beginning from the location of the light source, through the center of the aperture A, and to the image plane 1. This geometry can be used to determine the direction of the light source relative to the imaging apparatus. The imaging apparatus has a diffraction element, such as a diffraction grating, in the path of light through the aperture and disposed within or very near the aperture, for receiving incident light passed through a small aperture A. The light-transmitting area of aperture A is smaller, and typically much smaller, than the imaging area of interest on image plane 1. The zero-order light transmits through the grating and is received at image plane 1, spaced apart from the aperture A. The zeroth diffraction order light on image plane 1 is a geometrical projection of aperture A along the central ray from the light source. The intensity distribution of the zeroth diffraction order light on image plane 1 is determined by factors such as type of light source and distance.

The incidence position of the transmitted laser light has particular x-y coordinates; these coordinates indicate the elevational and azimuthal angles of the laser light source relative to image plane 1. Reference axis N is normal to image plane 1 and passes through the center of the small aperture A.

FIG. 1B is a schematic diagram that shows detection principles of FIG. 1A in an environment having multiple light sources of different types and located at different angles, directed toward, or in the FOV of, the device, along with scene content. Light sources at different azimuth and elevation relative to the apparatus have corresponding x-y coordinates in image plane 1. The presence of other, non-laser light sources, particularly sources of bright light, complicates the task of identifying and characterizing laser light sources. However, the geometry described can generate a distinct spatial/spectral signature image providing ability to discriminate various types of light from laser sources. Spatial characteristics of interest for the generated light pattern can include shape, position, concentric rings, and average pixel value of a pattern feature, for example. Thus, laser sources, which have very narrow spectral bands and, overall, well-delineated spectral content or spectral distribution and are treated, in practice, as essentially monochromatic, with the bulk of the emitted light energy at a single wavelength, can be distinguished from other broadband sources including the polychromatic Sun, LED, incandescent, halogen, or other sources that have broader spectral content, with energy distribution over a range of wavelengths, than lasers. Laser sources having different wavelengths can also be distinguished from each other and from other types of sources by characterizing their spectral content and energy distribution.

FIG. 1C shows an exemplary distribution of light on image plane 1 of FIG. B where there are multiple light sources as shown in FIG. 1B and where there is a one-dimensional diffraction grating. As described with reference to FIG. 1B, the x-y dimensions of the 0th order and +/−1 order diffracted light relate directly to the relative elevation and azimuth angle of the light source. (It can be noted that the x-direction of the light sources in the FIG. 1C representation is inverted relative to FIG. 1B.)

Spectral distribution is characteristic of each type of light source, generally as follows:
(i) Light from the Sun is diffracted near aperture A to provide 0th diffraction order light and, at least, the diffraction orders −1 and +1. The 0th order light is spatially concentrated. Because the sunlight is highly polychromatic, diffraction orders −1 and +1 exhibit significant spectral dispersion, forming a “smeared” or highly elongated image of the aperture A, which can be described as “spectral smearing”.
(ii) The 0th diffraction order LED light at the image plane 1 in FIG. 1C is also concentrated and forms a clear image of the aperture. The LED light energy has spectral content distributed over a narrower wavelength band than is sunlight, so that −1 and +1 diffraction orders exhibit relatively moderate spectral dispersion.
(iii) For laser light, with its narrow wavelength band, −1 and +1 diffraction orders do not exhibit spectral dispersion and are spatially concentrated, resembling the 0th order image in terms of light distribution at the image plane.

Various spectral characteristics of a light source can be detected including wavelength values and range, one or more peak wavelengths, energy distribution over the spectrum, and other spectral features allowing differentiation of many types of light sources.

In embodiments described herein, the location of the laser is determined by the corresponding position of the central 0th diffraction order on the imaging array, formed as a geometric projection of aperture A onto the image plane along the central ray direction. The path of the central ray from the light source may be altered by the presence of windows, mirrors and other optical components, even components with some curvature. The geometric projection of aperture A can have significant blurring or lack of definition along the outer edges, but takes its shape and overall outline from the aperture shape, as the term implies. The light distribution within the 0th diffraction order may also contain intensity oscillations caused by diffraction.

The distance between the 0th order light and the resulting images of aperture A from the +/−1″ orders corresponds to the laser's wavelength. Specifically, the angular separation between diffraction orders is given by the grating equation and depends on factors including wavelength, the pitch of the grating, and the incident angle with respect to the normal axis.

Although an image sensor, such as a CMOS sensor, can be placed at image plane 1 to capture the light distribution for the purpose of detecting lasers present within the field of view, there are several practical situations where such a configuration may not work well. One such situation is detection of laser wavelengths longer than 1000 nm, and especially longer than 1100 nm, where silicon-based image sensors are not suitable. Although laser wavelengths in the shortwave infrared (SWIR) range between 900 and 1700 nm (or even longer) can be detected using InGaAs based image sensors, for example, the cost of such non-silicon image sensors can be cost 100 times greater than mass produced silicon-based CMOS sensors.

A second challenge arises when the desired size of the imaged region in image plane 1, based on field of view and ability to discern laser wavelength and location, is larger than the active area of the image sensor. In this case, it is necessary to demagnify the image produced at image plane 1.

Yet another situation arises when a large field of view is desired but wiring or other structures on the image sensor chip cause vignetting for larger angles of incident light, as is often the case for front-illuminated CMOS sensors.

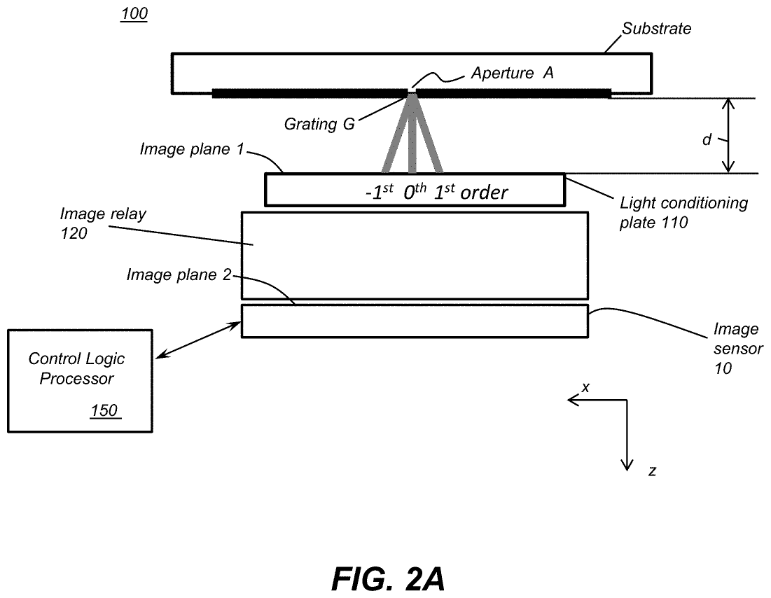

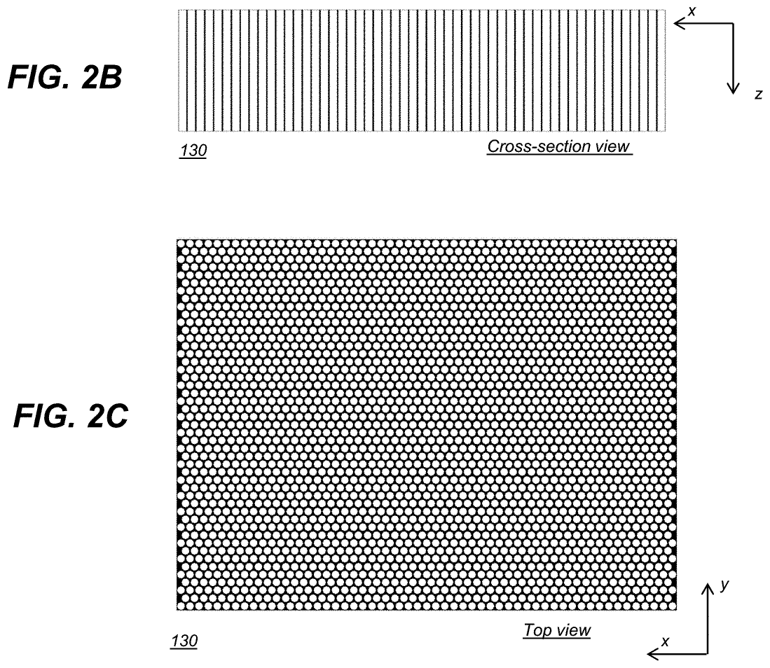

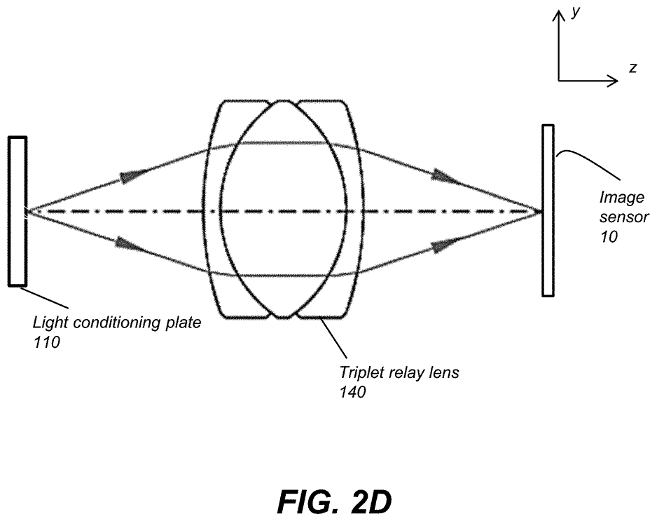

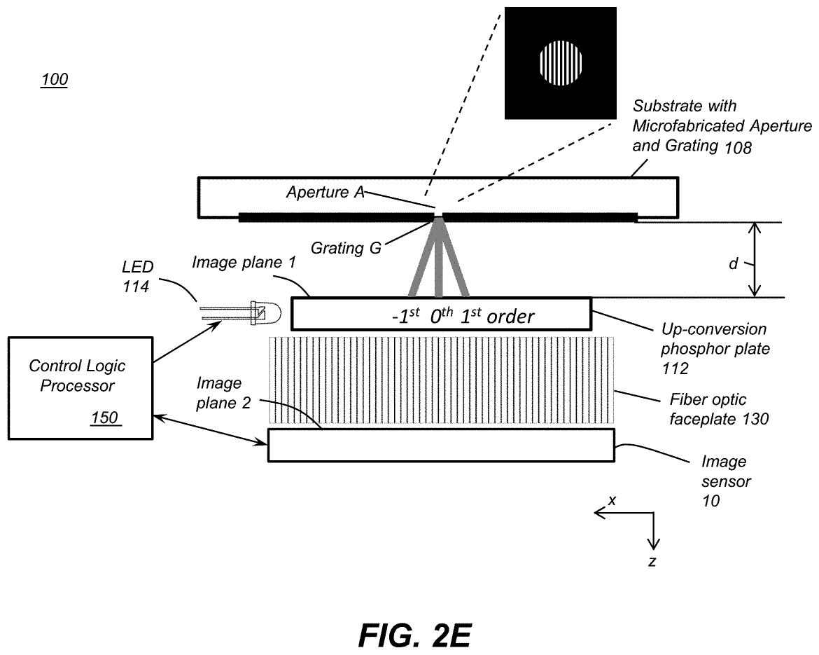

FIG. 2A is a simplified schematic diagram, from a side view, showing the primary components of a compact laser detection apparatus 100, which can be provided as a single packaged unit. Components of detection apparatus 100 can include a transparent substrate (window) with a nearby aperture A and a diffraction grating G at or very near aperture A that generates diffraction orders. An optional light conditioning plate 110, such as a component providing spectral conversion, can be used to modify the properties of the light distribution at image plane 1, if so desired. An optical image relay 120 forms a relayed image from image plane 1 onto the active area of image sensor 10, located at image plane 2. In optical parlance, optical relay 120 thus relays image plane 1 to image plane 2. A control logic processor 150, in signal communication with image sensor 10 at image plane 2, can be programmed to generate signals indicative of detected features of the light sources, including at least the wavelength or wavelength range and angular direction, for example, along with other characteristics, such as type of light source, whether laser or non-laser such as LED, sunlight, or incandescent light, and relative intensity, for example. FIG. 2A also shows diffraction orders for laser light that is on-axis, having an incident angle at a normal to image plane 1.

The image relay 120 can be a fiber optic faceplate, formed as illustrated in the magnified cross-sectional and top partial views, respectively, of FIGS. 2B and 2C. Such faceplates are available from multiple manufacturers, such as Schott AG and Incom, and contain arrays of adjacent optical fiber sections, formed using either glass or plastic fibers. These bonded arrays contain optical fibers that are typically 2.5 to 25 microns in diameter, providing a higher density of independent fiber light paths in practice than is suggested by the simplified and magnified portional illustrations in FIGS. 2B and 2C. A similar approach can be used to form a fiber optic array that is tapered, enabling magnification or demagnification between input and output.

Alternatively, the image relay can be a more conventional lens-based optical system, which can provide magnification or demagnification if required. The image relay can also employ a microlens array or a gradient index lens array. FIG. 2D shows an example of an alternative lens-based image relay with optics such as a Steinheil triplet achromatic lens 140 having unity magnification.

The light conditioning plate 110 shown in FIGS. 2A and 2D can modify properties of incident light before it is transmitted through the image relay 120. Various light properties can be altered depending on requirements of the compact laser detection apparatus 100. As illustrated, the front surface of light conditioning plate 110 is image plane 1; however, image plane 1 could also be at the back surface or at some other location, depending on the optical function of light conditioning plate 110.

According to an embodiment of the present disclosure, as shown, for example, in FIG. 2E, light conditioning plate 110 can provide wavelength conversion for the incident light, reducing cost and weight for SWIR (short-wave infrared) detection of laser light in the wavelength range 900-1600 nm by employing a standard imaging array designed for visible light, such as a CMOS (complementary metal oxide semiconductor) image sensor. For spectral conversion, light conditioning plate 110, labeled as up-conversion phosphor plate 112 in FIG. 2E, can have a surface with an up-conversion phosphor layer, such as a coating.

Up-conversion phosphors absorb longer wavelength photons, such as those in the 900-1600 nm wavelength range, and emit photons at shorter, higher energy wavelengths that can be readily imaged using low-cost visible light image sensors such as CMOS image sensors. One commercially available example of an up-conversion phosphor is Lumitek Q-42 from LUMITEK International, Inc. (Ijamsville, MD), which has an emission peak at 640 nm. This type of up-conversion phosphor requires charging by a visible light source in order to provide conversion of higher wavelength energy. Charging can be provided using an external visible light source, such as by an LED, energized to replenish the phosphor charge when the image sensor exposure is momentarily turned off. In practice, the image sensor 10 could run at a fixed frame rate, with an exposure time window in each frame that is shorter than the overall time interval between frames. The phosphor charging LED can be energized as needed, during an interval that is outside of the exposure/detection time window. Alternatively, if the phosphor-charging LED emits shorter wavelengths (for example, light in the ultraviolet to green range), those wavelengths can simply be blocked using a long-pass filter which transmits the light emitted by the up-conversion phosphor.

For other embodiments of laser detection apparatus 100, the light conditioning plate 110 can be a transmissive surface diffuser (e.g. a rear projection screen). In this case, image plane 1 contains a real image and light emerging from the diffuser has a broadened angular distribution. The reimaged light distribution at image plane 2 is then compatible with a broader range of image sensors, including front-illuminated CMOS sensors, having features on the image sensor die that could otherwise cause significant vignetting. A diffuser can be formed using a rough surface or using micro-lenses, for example.

A side benefit of both up-conversion phosphor and transmissive diffuser embodiments is the potential to reduce saturation or damage of the image sensor 10 in the presence of intense laser energy.

Alternatively, light conditioning plate 110 could use a more common phosphor coating that provides “down-conversion”, transforming shorter wavelength light energy, such as ultraviolet and/or blue light, to longer wavelength visible light energy, such as yellow or red light. The light conditioning plate could also be an optical filter that only transmits certain wavelengths or that transmits or reflects light according to its polarization. It can also be a neutral-density filter that reduces the intensity of transmitted light, thus providing an alternate method for reducing the potential of image sensor saturation or damage.

FIG. 2E shows an embodiment of compact laser detection apparatus 100 that has both an up-conversion phosphor plate 112 for converting SWIR light to wavelengths that can be imaged using a silicon-based image sensor and a fiber optic faceplate 130 for relaying the image. Light from LED 114 is coupled into the edge of phosphor plate 112 to enable uniform light charging of the up-conversion phosphor coated on one of the plate 112 surfaces. The FIG. 2E configuration can also have one or more spectral filters, such as filters disposed to block LED light from other portions of the optical path.

Microfabrication techniques, such as those used in semiconductor or MEMS (MicroElectroMechanical Systems) fabrication, can be used to integrate some components, for example, integrating the aperture and diffraction grating onto a transparent substrate 108. Although FIG. 2E shows a microfabricated substrate with aperture A and grating G on the bottom surface of the substrate, other embodiments can have the aperture and grating on the opposite surface.

A microfabricated substrate could consist of a thin metal layer, such as chrome or aluminum, deposited on a glass or quartz substrate. The metal layer would be lithographically patterned to form an aperture with grating features formed within the aperture. Outside of the aperture region, the metal layer would be sufficiently opaque to block bright laser light from reaching image sensor 10.

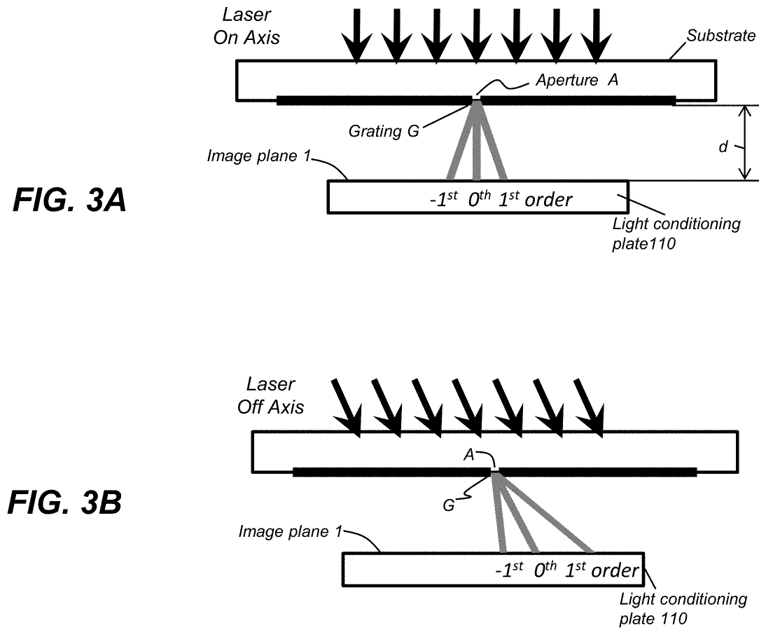

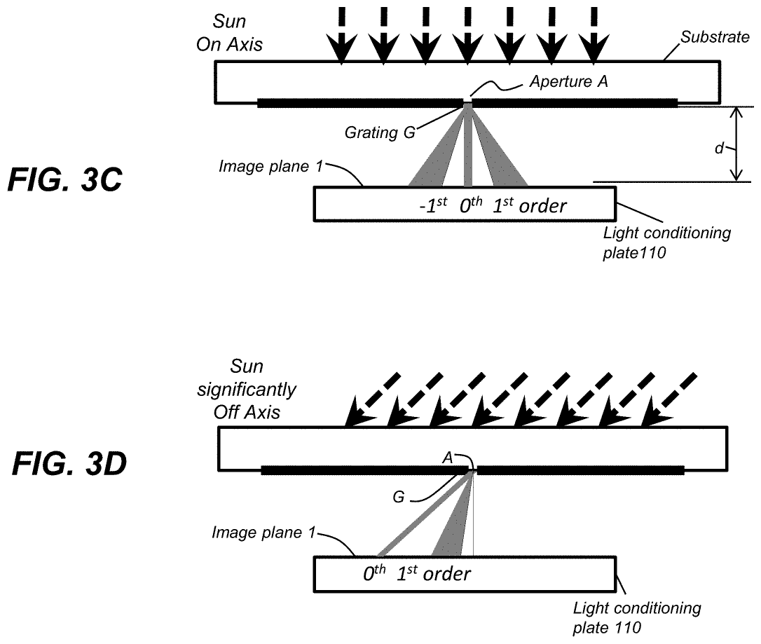

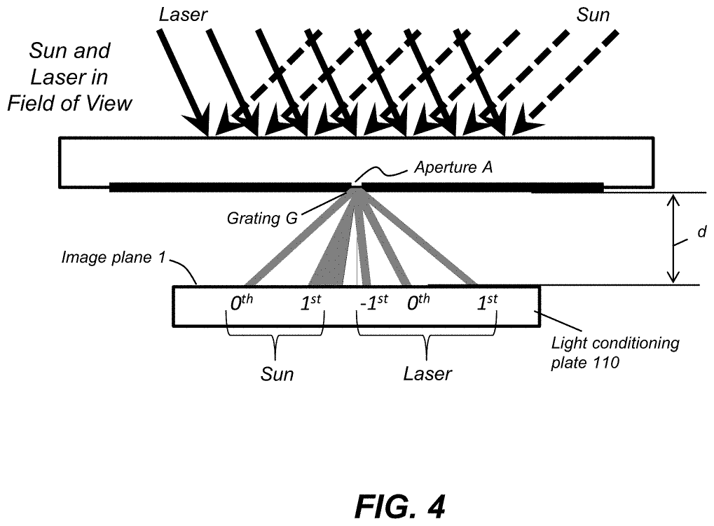

In the embodiment of FIGS. 3A through 4, the diffraction grating G is disposed very near to, or formed within or along, the aperture A. Distance d shown in FIGS. 3A through 4 relates to the relative displacement of image plane 1 from aperture A and diffraction grating G. In practice, reducing distance d increases the FOV but decreases the spatial separation of diffraction orders on image plane 1. The aperture A and diffraction grating G can be formed on the same substrate.

Referring to FIG. 3A, where the laser light source is on-axis, with incident angle at a normal to image plane 1, the respective −1 diffraction order and the +1 order light distributions are equally spaced from the image of the aperture A generated by the 0th order light. As the laser light source moves further off-axis, as in FIG. 3B, locations of diffraction orders and spatial distances between 0^{th} and +/−1^{st} orders change correspondingly.

In similar manner, FIGS. 3C and 3D are simplified schematic diagrams showing diffraction of on-axis and off-axis sunlight, respectively. Where the sunlight is on axis, as in FIG. 3C, the respective −1 order and the +1 order light distributions are equally spaced from the 0^{th} order light. As the angle of the sun moves away from normal, the diffraction orders shift position accordingly. In the example of FIG. 3D, the −1^{st} order is shifted so far to the left that it no longer falls on light conditioning plate 110. Shorter wavelengths are diffracted by a smaller amount than longer wavelengths. Therefore, the corresponding short-wavelength portions of −1 and +1 orders are closer to the 0^{th} order than the corresponding long-wavelength orders.

FIG. 4 is a simplified schematic diagram that shows diffraction effects wherein both a laser source and the sun are within the field of view and each of the light inputs is at an off-axis angle. As multiple light sources can be expected in many environments where laser detection is needed, the particular diffractive signature of the light at image plane 1 distinguishes light sources and can be used to identify their relative wavelengths and positions.

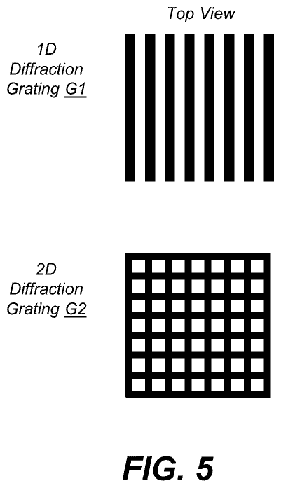

In order to more accurately characterize light sources and to distinguish or isolate the laser light source for further analysis, embodiments of the present disclosure can use diffraction gratings of various types. One familiar type of diffraction grating is a 1D (one-dimensional) amplitude grating G1, represented in FIG. 5. The light-blocking grating features for 1D amplitude grating G1 are linear and in parallel, extending along one direction. Inter-line spacing can be optimized to cover a particular range of wavelengths, including well-defined laser wavelengths of interest. The diffraction efficiency of a 1D amplitude grating G1 is relatively insensitive to wavelength, making it useful over a range of wavelengths and thus generating a distinctive diffraction “signature” for numerous laser types. For example, an ideal 1D amplitude diffraction grating similar to the type shown in FIG. could have a diffraction efficiency of 10.1% into each of the +1 and −1 diffraction orders and 25% into the zero order, independent of wavelength. A phase grating could alternately be used for laser detection; however, phase gratings are generally much more sensitive to wavelength. Thus, a phase grating may be more useful in an application where laser light within a specific wavelength range must be detected.

For enhanced detection capability, a 2D (two-dimensional) diffraction grating can be used. FIG. 5 compares structure of a portion of a 1D diffraction grating G1 with a portion of a 2D diffraction grating G2. The 2D grating G2 structure in FIG. 5 has two sets of diffraction features, aligned orthogonally to each other. For example, an ideal 2D amplitude diffraction grating G2 similar to the type in FIG. 5 could have a diffraction efficiency of 2.53% into each of the four primary first diffraction orders, (+1, 0), (−1, 0), (0, +1) and (0, −1), and 6.25% into the zero order, independent of wavelength. Although low efficiency is a concern for many types of systems, it can be an advantage when attempting to detect very bright sources such as lasers where image sensors can be saturated or even destroyed. Other types of 2D diffraction structures may also be employed, for example a grating with unit cells disposed in a hexagonal grid pattern.

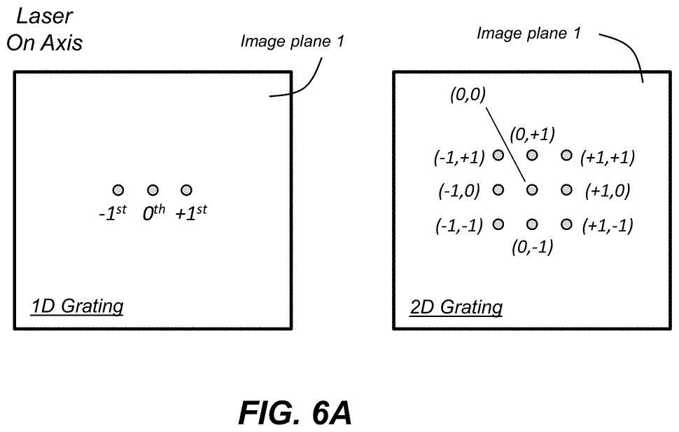

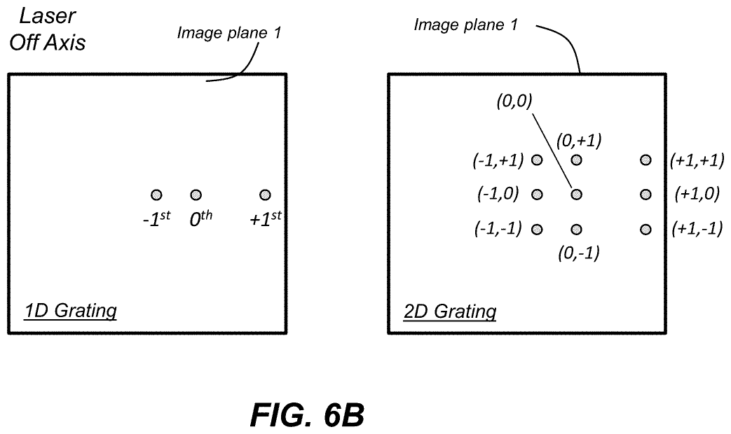

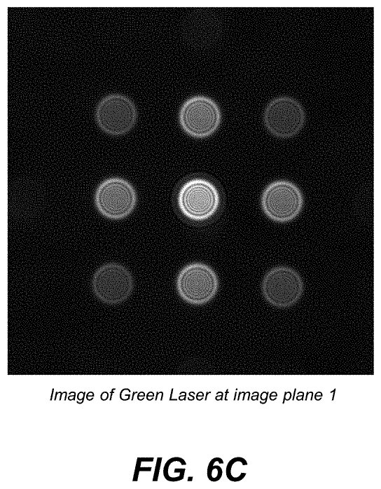

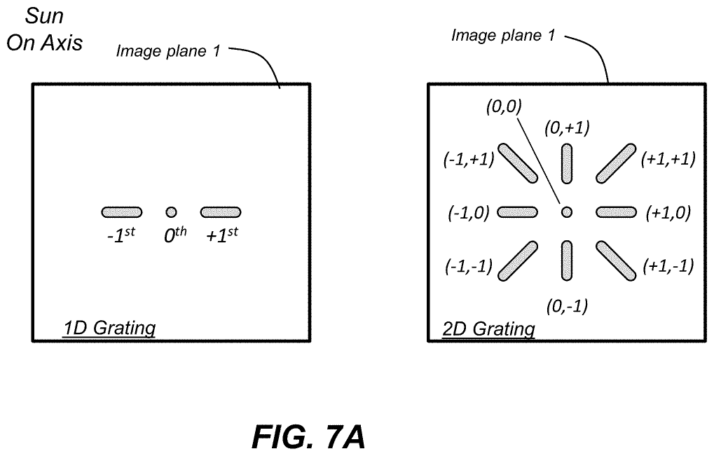

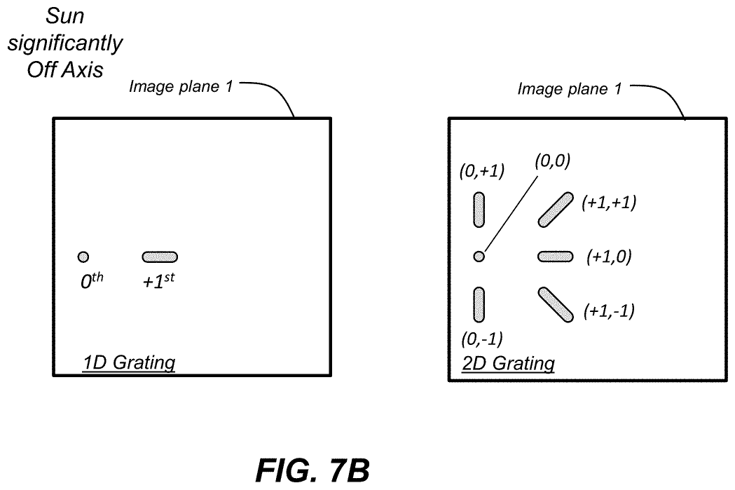

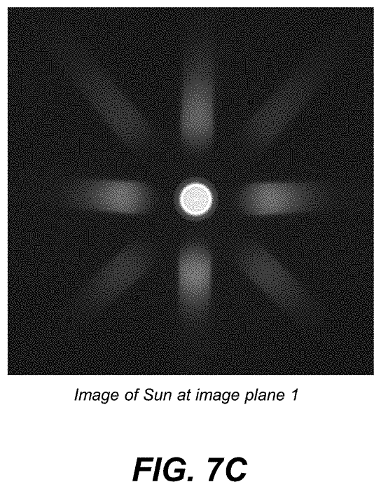

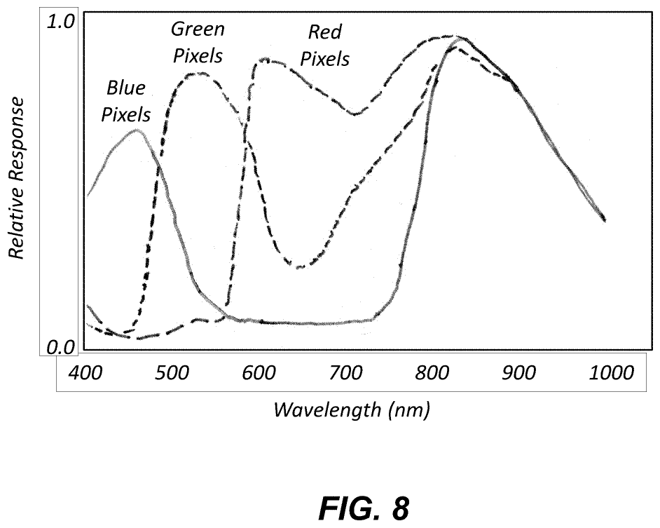

FIGS. 6A through 7B provide comparison of 1D and 2D grating results of light pattern distribution on the image sensor, in simplified schematic form. Orders corresponding to the 1D grating G1 are single digits; orders corresponding to the 2D grating G2 include two coordinate digits. As shown at the left in FIGS. 6A and 6B, for on- and off-axis laser sources, respectively, the conventional 1D grating G1 generates diffraction orders disposed along a single line. For comparison, light pattern results for the 2D grating G2 consist of a 2-dimensional distribution of diffraction orders as shown at the right in FIGS. 6A and 6B. The grid of diffraction orders for 2D gratings in FIGS. 6A and 6B is representative and may be more complex in practice, for example with hexagonal gratings and/or large off-axis angles. Higher orders of diffraction, such as +2 and −2 diffraction orders, may be present as well but are not shown in FIGS. 6A and 6B.

FIG. 6C shows an example image showing diffraction for a green laser on or near the device axis for a system with a 2D grating G2 (FIG. 5) and a circular aperture. As is typical for laser light energy, all diffraction orders have a similar shape corresponding to the circular aperture shape, with no apparent smearing of non-zero diffraction orders. Furthermore, concentric rings from Fresnel diffraction effects are visible in the diffraction orders and can further assist in differentiating lasers from other types of light sources.

The schematic diagrams of FIGS. 7A and 7B show the diffraction signature of on- and off-axis sunlight, respectively. FIG. 7C shows an example image for sunlight on or near the device axis for a 2D grating G2 (FIG. 5). The central zeroth order (0, 0) is brightest by far. The substantial elongation of the eight non-zero diffraction orders is a result of spectral dispersion, as noted previously.

Using the method described with reference to FIGS. 2A-7C, the source of a laser can be accurately determined according to the position of the central 0^{th} diffraction order on the image sensor. The distance of the 0^{th} order light to the +/−1st diffraction orders, combined with position, can indicate the laser's wavelength. Furthermore, the optical power density of light from the laser can be estimated from the brightness of the 0^{th} order, as measured by the image sensor and adjusted for system parameters such as exposure time, measured wavelength and (transmission) efficiency into the 0^{th} order.

The Applicant has adapted principles of light diffraction, in one or two dimensions, to provide a laser detection system that allows compact packaging and imaging, at relatively low cost. This allows the apparatus of the present disclosure to be scaled to appropriate size for personnel or other equipment that require laser detection.

Image sensor 10 can be any of a number of suitable imaging arrays. For example, CMOS image sensors such as the Sony IMX178 CMOS sensor with back-illuminated pixels can be used for wavelengths between 400 and 1000 nm; Sony IMX990/991 sensors are receptive to a broad wavelength range between 400 and 1700 nm, i.e., extending from visible to shortwave infrared (SWIR) wavelengths. As noted earlier, back illumination be advantageous for achieving wide field of view because it minimizes obscuration by wires on the sensor die; unintended effects such as a reduction in effective field of view can be the result of obstructed light paths and light at high angles.

Embodiments of the present disclosure can employ either monochrome or multi-color image sensors. In some cases, the red, green, and blue (RGB) pixels on multi-color image sensors can be used to further improve detection capabilities. As an example, FIG. 8 shows the spectral response of a multi-color image sensor that can image wavelengths from blue (400 nm) to near-infrared (1000 nm). The plot in FIG. 8 contains separate curves for red, green, and blue pixels. For visible wavelengths below 700 nm, blue pixels are sensitive primarily to blue light, green pixels to green light, and red pixels to red light. However, all three types of pixels are sensitive to near-infrared light with wavelengths longer than approximately 800 nm.

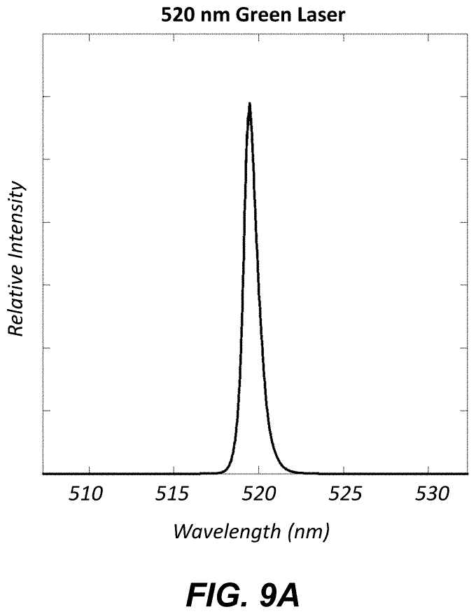

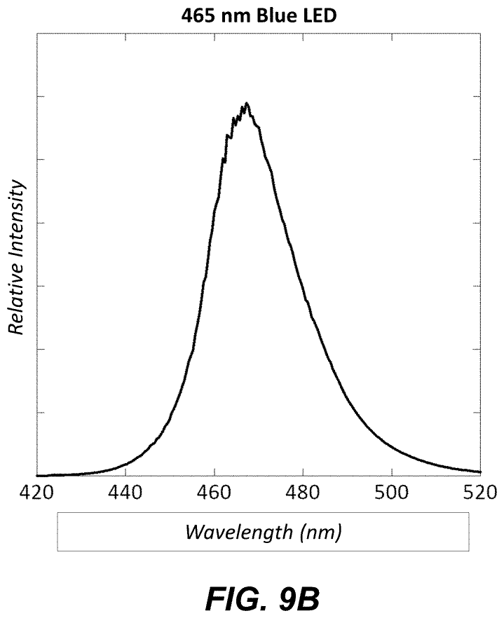

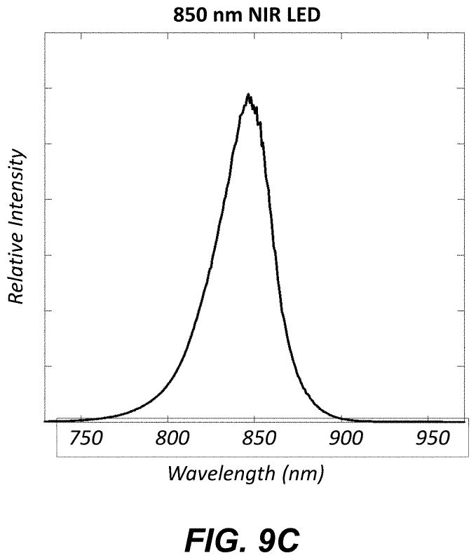

The image data from multi-color image sensors can be separated into red, green, and blue images. In embodiments of the invention with color image sensors, the diffraction orders from different types of light sources will produce significant differences in the corresponding RGB images. For example, in an embodiment of the invention that has a color image sensor with a spectral response similar to FIG. 8, a 520 nm green laser with a relatively narrow spectrum similar to FIG. 9A will produce primarily a green image with distinct diffraction orders, which can be similar to the orders visible in FIG. 6C. A 465 nm blue LED with a relatively wide spectrum similar to FIG. 9B, will produce a blue image with blurred diffraction orders and, as a result of the relatively wide spectral width, a lower intensity green image that also contains blurred diffraction orders. Lastly, an 850 nm near-infrared LED with FIG. 9C spectrum will produce red, green, and blue images that are very similar and that have blurred diffraction orders. The similarity of red, green, and blue images for this case is due to the similar spectral response of red, green, and blue pixels for wavelengths near 850 nm, which is apparent from the curves of FIG. 8.

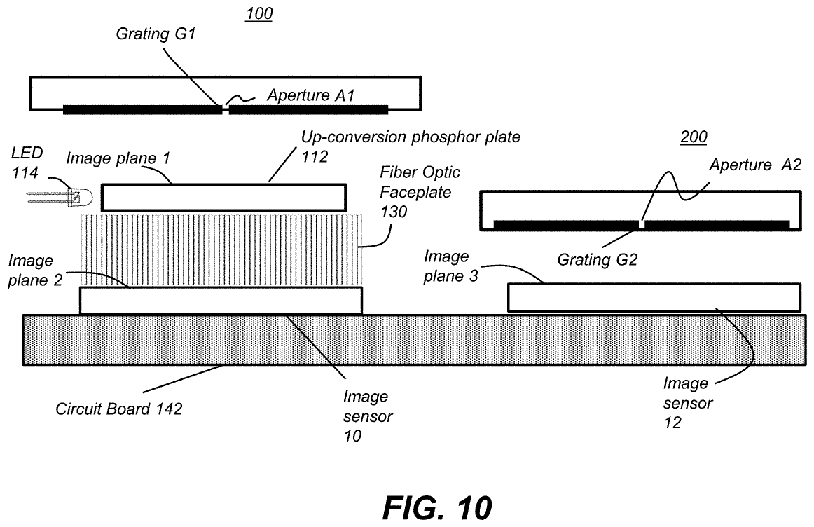

FIG. 10 shows an embodiment that can simultaneously detect visible and short-wave infrared (SWIR) lasers, or typically cover a wavelength range from 400 to 1600 nm. This embodiment has a laser detection apparatus 100 for detecting sources emitting SWIR wavelengths of the type shown in FIG. 2E and a second laser detection apparatus 200 for sources emitting visible wavelengths. In laser detection apparatus 200, image sensor 12 is placed at image plane 3 directly after aperture A2 and grating G2 without an image relay. Both laser detection apparatuses 100 and 200 would have low-cost silicon-based image sensors, which could be mounted on a common circuit board 142.

Another embodiment for simultaneous detection of visible and short-wave infrared (SWIR) lasers uses a thin up-conversion phosphor layer on light conditioning plate 110 of FIG. 2A. In this embodiment, the thin up-conversion phosphor layer is capable of both converting SWIR light (wavelength >˜1000 nm) to shorter wavelengths and passing a portion of incident light with shorter wavelength (wavelength <˜1000 nm) towards the image sensor. Image relay 120 then forms an image at image plane 2 from both up-converted short-wave infrared light and non-converted light, at wavelengths that can be imaged with a single silicon-based image sensor.

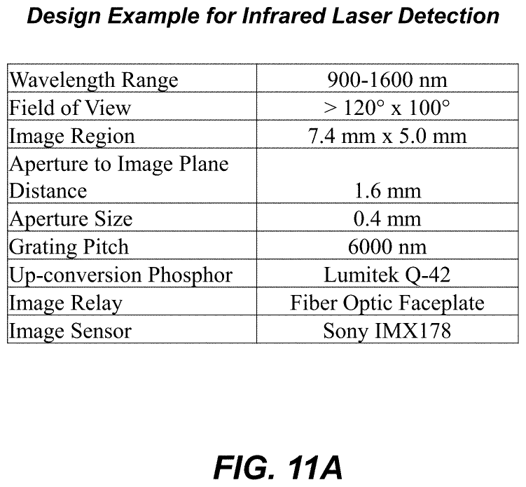

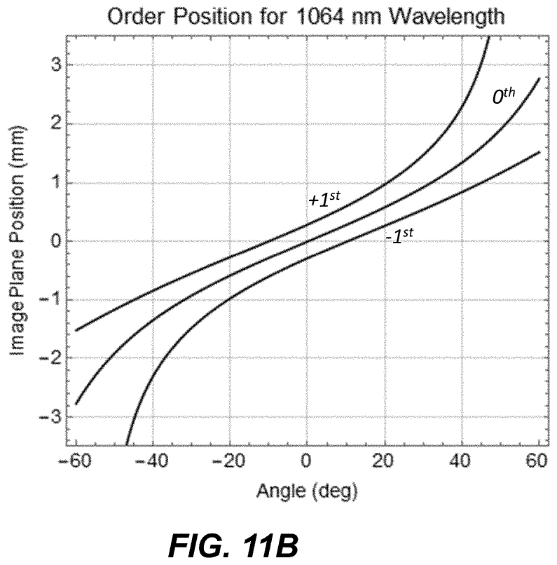

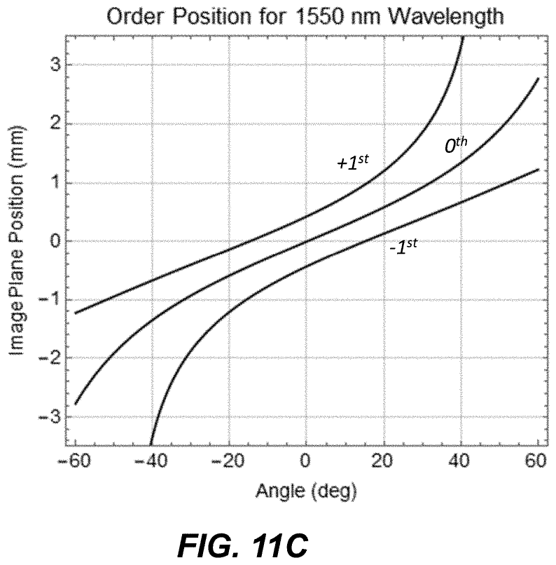

FIG. 11A shows an example of specifications for an infrared laser detection apparatus based on the embodiment illustrated in FIG. 2E. FIGS. 11B and 11C show plots of the calculated position of diffraction orders on image Plane 1 for a system that has the same specifications as in FIG. 11A. FIGS. 11B and 11C relate to laser wavelengths of 1064 nm and 1550 nm, respectively. The incident angle for these figures varies in a plane perpendicular to the grating lines. As expected, the 0^{th} order position is independent of wavelength but varies monotonically with angle, enabling the determination of the angular direction of incident light. The position of the two first diffraction orders is calculated using the grating equation. These plots illustrate the fundamental physical principles used to determine laser position and wavelength. Practical automated implementation in a laser detection system 100 requires a robust image analysis algorithm.

The Applicant has found that the laser signature is unique and clearly distinguishable from sunlight, LED emission, and other light sources. Laser orders appear in sharp contrast. Furthermore, Fresnel diffraction effects (concentric rings) can be visible in diffraction orders of laser sources. By comparison, sunlight and LED source image content can be readily distinguished from laser image content by their smeared non-zero diffraction orders due to their relatively broad wavelength spectrum compared with the laser.

Use of the basic principles and structures described herein allow a micro-fabricated device to be capable of identifying the source position, wavelength, and relative intensity of a laser and to distinguish laser light from other natural and man-made sources. The flexibility and robustness of the Applicant's approach allows a number of embodiments. For example, the detection apparatus can have multiple apertures with corresponding gratings optimized for different wavelength ranges. The apertures may have different dimensions and the gratings may have different grating periods.

Control logic processor 150, in signal communication with image sensor 10, can employ a variety of different image processing and detection techniques to automatically determine light source type, wavelength or wavelength range, and angular direction from the diffraction orders. According to an embodiment of the present disclosure, machine learning techniques can be used to “train” a detection apparatus for improved recognition of lasers and various types of light source, such as automobile headlights, floodlights, etc, in the presence other background objects in the scene.

Embodiments of the present disclosure can be very small and light weight, enabling wearable laser detection if desired. Multiple laser detection apparatus can be arranged to detect incident laser from different angles to expand the range of angles over which light sources can be characterized. Because of their light weight and low-cost design, multiple units can be used simultaneously to provide comprehensive coverage for a variety of vehicles or buildings.

The invention has been described in detail with particular reference to a presently preferred embodiment, but it will be understood that variations and modifications can be effected within the spirit and scope of the disclosure. It should be noted that a number of modifications can be made to the optical design described herein, within the scope of the present disclosure. For example, the optical image relay can include reflective or partially reflective optical surfaces that fold the optical path, such as for more suitable positioning of image sensor 10 or that split the optical path, such as to employ more than one image sensor 10.

The presently disclosed embodiments are therefore considered in all respects to be illustrative and not restrictive. The scope of the invention is indicated by any appended claims, and all changes that come within the meaning and range of equivalents thereof are intended to be embraced therein.

1. An apparatus for characterization of one or more light sources over a field of view, comprising:
a) an image relay disposed to relay a first image plane to a second image plane;
b) an aperture disposed to define the field of view at the first image plane;
c) a diffraction grating in the path of light through the aperture and configured to form, on the first image plane, for at least one light source, a light pattern having at least two diffraction orders of light from the corresponding light source;
and
d) an image sensor array configured to provide image data from the light pattern at the second image plane.

2. The apparatus of claim 1 wherein the at least two diffraction orders comprise at least a zeroth diffraction order and a first diffraction order.

3. The apparatus of claim 1 further comprising a control logic processor in signal communication with the image sensor array and configured to provide a signal that identifies at least a wavelength range and an angular direction within the field of view for the at least one light source according to the corresponding light pattern.

4. The apparatus of claim 1 further comprising a control logic processor in signal communication with the image sensor array and configured to provide a signal that identifies a laser light source.

5. The apparatus of claim 1 wherein the diffraction grating lies within the aperture.

6. The apparatus of claim 1 further comprising a light conditioning plate configured to modify at least one of wavelength, polarization, intensity, and phase of the light that is transmitted through the aperture and incident on the first image plane.

7. The apparatus of claim 1 further comprising a light conditioning plate with an up-conversion phosphor disposed near the first image plane.

8. The apparatus of claim 1 wherein the image relay comprises a fiber optic array.

9. The apparatus of claim 1 wherein the diffraction grating is a two-dimensional diffraction grating.

10. The apparatus of claim 1 wherein the diffraction grating is an amplitude grating.

11. The apparatus of claim 1 wherein the aperture and the diffraction grating are formed on a common substrate.

12. The apparatus of claim 1 wherein the image sensor array is a multi-color sensor.

13. The apparatus of claim 1 further comprising a diffuser for light that is transmitted through the aperture and incident on the first image plane.

14. A laser detection apparatus comprising:
a) an aperture that is disposed in a light path to a first image plane and that defines a field of view;
b) an image relay disposed to relay the first image plane to a second image plane;
c) a diffraction grating in the light path configured to form, on the first image plane, for a corresponding light source in the defined field of view, a diffraction light pattern having at least a zeroth diffraction order and a first diffraction order of light from the light source;
d) an image sensor array disposed to receive the relayed diffraction light pattern at the second image plane; and
e) a control logic processor in signal communication with the image sensor array and configured to provide a signal that identifies laser light according to the corresponding diffraction light pattern.

15. The laser detection apparatus of claim 14 wherein the zeroth diffraction order is a geometric projection of the aperture.

16. The laser detection apparatus of claim 14 wherein the control logic processor is further configured to report angular direction and wavelength of the light source.

17. The laser detection apparatus of claim 14 further comprising a phosphor layer disposed near the first image plane.

18. The laser detection apparatus of claim 14 wherein the image relay comprises either a fiber optic faceplate or at least one lens.

19. A method for analyzing light comprising:
providing a light path, extending through an aperture, for light from a light source;
disposing a diffraction element in the light path for the apertured light;
defining a first image plane in the path of diffracted light from the diffraction element;
relaying the first image plane to a second image plane;
interpreting a diffraction pattern formed at the second image plane in order to characterize spectral content and an angular disposition of the light source according to the diffraction pattern;
and
providing a signal indicative of the spectral content of the light source and angular disposition.

20. The method of claim 19, wherein the diffraction element is a grating.
